(19) United States
(12) Patent Application Publication
(10) Pub. No.: US 2022/0104381 A1
(43) Pub. Date: Mar. 31, 2022

(54) MODULE FOR DIGITAL DISPLAY PANEL AND ASSOCIATED DIGITAL DISPLAY PANEL

(71) Applicant: PRISMAFLEX INTERNATIONAL, Haute-Rivoire (FR)

(72) Inventors: William Dulieu, Montrond Les Bains (FR); Jeffrey-Changbing Jiang, Lissieu (FR)

(21) Appl. No.: 17/487,857

(22) Filed: Sep. 28, 2021

(30) Foreign Application Priority Data
Sep. 28, 2020 (FR) 2009857

(51) Int. Cl. H05K 7/14; G09F 9/33

(52) U.S. Cl. CPC H05K 7/1452; G09F 9/33

(57) ABSTRACT

A module for a digital display panel includes an electronic board, a first face of which has an array of light-emitting diodes arranged in rows and columns with a substantially constant pitch. The module further includes a frame fastened onto a second face of the electronic board opposite the first face and at least one water-permeable connector for an optical fiber, mounted on the frame. The frame includes a baseplate integrating the at least one water-permeable connector. The module includes a cover attached to the baseplate so as to form a watertight volume inside the baseplate. The cover includes at least one opening provided with sealing means intended to ensure sealing around at least one optical fiber connected to the at least one water-permeable connector.

### TECHNICAL FIELD

The present disclosure relates to the field of display panels, and more specifically to digital LED display panels. The disclosure relates more particularly to a watertight module for forming such a digital display panel.

### BACKGROUND OF THE DISCLOSURE

Generally speaking, digital display panels are appreciated for their ability to allow an almost infinite number of changes in the images or messages to be displayed, limited only by the memory capacity of the central electronic unit that runs such panels. These panels also have the advantage of being able to display animated images, which makes them an increasingly popular advertising medium. These panels can also be connected to a remote server in order to modify a poster campaign being broadcast on the panel, quickly and without operator intervention.

These digital display panels comprise a plurality of light-emitting diodes (LEDs), arranged in a matrix, and capable of being individually illuminated according to the desired display. Various hardware architectures can be envisaged, and in particular those described in document U.S. Pat. No. 5,949,581 wherein the panel comprises a plurality of modules, each containing a few hundred LEDs.

Typically, the modules are assembled in sealed cabinets containing several rows and columns of modules. Multiple cabinets can then be assembled, also in multiple rows and columns of cabinets to form the digital display panel.

To limit the weight of the digital display panel, it is known to eliminate the cabinets by using watertight modules mounted directly on a panel structure. To do this, each module must be able to process the data to be displayed and receive the power necessary to operate the electronic circuits and light-emitting diodes.

In general, a module comprises an electronic board, a first face of which has an array of light-emitting diodes arranged in rows and columns with a substantially constant pitch. The second face of the electronic board integrates the LED management circuit as well as the connectors for power and data.

Typically, data transfer is accomplished using cables with embedded wires, such as Ethernet cables, commonly referred to as “RJ45” cables, or “SATA” cables, which stands for “Serial Advanced Technology Attachment”. These cables have the advantage of being flexible and therefore easy to install in small spaces. Although these cables are usually shielded, they are still sensitive to electrical interference from, for example, a transformer in the module's power supply. Moreover, the data transfer capacity of these cables is limited, around 10 Mbits/s in RJ45 cable, and 150 Mbits/s in SATA-I cable.

In addition, these cables with metal wires carry data via electrical currents, generating electromagnetic waves depending on the frequencies used for data transfer. For example, the frequencies used in Ethernet cabling range from 100 MHz to 1000 MHz, and those used in SATA cabling range from 750 MHz to 3000 MHz.

As a result, electromagnetic compatibility is hampered: not only that of the module, but even more so that of the panel which includes multiple modules.

The use of metallic cables therefore requires the use of additional protection, which may be extensive shielding of the cables or filters, such as ferrites surrounding the cables.

In order to achieve a higher data transfer speed, for example 200 Mbit/s, it is possible to use optical fibers. They are also insensitive to electromagnetic disturbances, since data is not transported with electricity but with light. In addition, since optical fibers do not contain any metallic elements, they are naturally more resistant to oxidation if their protective sheaths are damaged.

On the other hand, optical fibers, whose core is generally made of glass or rigid plastic, cannot be bent at the risk of breaking said core. Nor can they be bent with such small bending radii as electrical cables to ensure the transmission of light information.

To obtain a watertight module, the connectors of the module allowing to receive the power supply and the data correspond classically to watertight connectors. When the connectors are fixed on the second face of the electronic board, this second face is covered with a resin ensuring the sealing of the components.

Sealed connectors for RJ45 type cables are commonly available on the market and the cable technology lends itself well to this type of connector, since the contacts within the connector are each made by a pair of deformable plugs that come into contact with each other by pressure. It is therefore no great difficulty to make watertight RJ45 cable connectors.

On the other hand, fiber optic connectors are more complex to make because the interface between the two fibers to be connected must be free of dust or dirt, the cut of each fiber must be orthogonal to the fiber, the two fibers to be connected must be coaxial, and the two fibers must be brought into contact and pressed against each other for their connection.

The pressure required to make an effective connection between two optical fibers must be applied longitudinally with respect to the optical fibers. However, to make a watertight connector, it is necessary to apply a radial pressure to a cable or an optical fiber. As a result, watertight connectors for optical fibers are particularly complex and expensive, as they must be adapted to achieve both longitudinal and radial pressure. In practice, it is found that connectors have either good sealing or good optical connection, but that the combination of these two properties is difficult to achieve.

The technical problem is therefore to provide a watertight module with at least one fiber optic connector that guarantees a good seal and a good optical connection.

### SUMMARY OF THE DISCLOSURE

In order to address this technical problem, the disclosed embodiments propose to use a watertight connector box integrating at least one water-permeable connector, i.e. a connector ensuring only optical connectivity so as to guarantee the efficiency of this optical connectivity. The watertight environment is created around the water-permeable connector by a baseplate on which a cover is mounted that mates with the baseplate. The cover has sealing means for at least one optical fiber to pass through. The sealing stress of the connector is thus transferred to the baseplate and the cover.

For this purpose, according to a first aspect, the embodiment relates to a module for a digital display panel, the module comprising:
an electronic board, a first face of which has an array of light-emitting diodes arranged in rows and columns with a substantially constant pitch;
a frame fastened onto a second face of the electronic board opposite the first face;
and at least one water-permeable connector for an optical fiber mounted on the frame.

In embodiments, the present disclosure is characterized in that the frame comprises a baseplate integrating the at least one water-permeable connector; and in that the module further comprises a cover attached to the baseplate so as to form a watertight volume inside the baseplate, the cover comprising at least one opening provided with sealing means intended to ensure sealing around at least one optical fiber connected to the at least one water-permeable connector.

The disclosed embodiments thus make it possible to obtain a watertight module incorporating a water-permeable connector ensuring the longitudinal pressure necessary for the effectiveness of the optical connection and sealing means ensuring the radial pressure necessary to guarantee the seal around the optical fiber connected to the module.

To do this, the sealing around the connector is also ensured by the mating of the baseplate and the cover.

Thus, the water-permeable connector is no longer exposed to water or dust.

The sealing means can take different forms, for example a gland or any other known form. In a preferred embodiment, the means for sealing the opening of the cover corresponds to a plug inserted into the opening. Inserting the plug into the opening causes radial stresses that the plug can transfer around the optical fiber. Thus, the plug provides a simple and effective way of ensuring a tight seal.

Advantageously, the plug has at least one orifice intended to allow the passage of an optical fiber having a predetermined diameter; the orifice comprising a frustoconical portion having a first cross-section whose diameter is greater than the predetermined diameter and a second cross-section whose diameter is less than the predetermined diameter; the first cross-section of the frustoconical portion opening out into the volume of the baseplate. In this way, the first section allows the fiber to be inserted into the plug without difficulty. In the second section, the optical fiber is slightly tightened, which guarantees the desired tightness and helps to hold the fiber in place.

In addition, the orifice also comprises a cylindrical portion opening, at a first end, onto the second section of the frustoconical portion; a second end of the cylindrical portion, opposite the first end, opening outside the volume of the baseplate. This second portion increases the length over which the fiber is slightly clamped, and allows for a better seal and better retention of the fiber.

Advantageously, the plug has protrusions extending radially from an outer face, the protrusions having an outer diameter greater than the internal dimensions of the plug opening so as to hold the plug in the cover opening by deformation of the protrusions. These protrusions also contribute to the sealing between the plug and the opening and to the transmission of radial stresses on the plug.

In a preferred embodiment, the baseplate comprises a partition rising from the frame, and the cover has a top membrane and an insert extending perpendicularly to the top membrane; sealing between the baseplate and the cover is provided by mating between the baseplate partition and the cover insert. The insert and the partition enable a large contact surface between the baseplate and the cover, limiting the penetration of water or dust in the watertight volume formed inside the baseplate.

In this embodiment, the baseplate partition and cover insert may comprise a front wall, a rear wall, and side walls. In such a case, the front wall of the baseplate partition has a depression facing the at least one water-permeable connector; the front wall of the cover has a protrusion whose shape corresponds to that of the depression of the front wall of the baseplate, and the at least one opening of the cover is formed in the front wall of the cover so that the at least one optical fiber can come to face the water-permeable connector. This arrangement allows the fiber to be delivered to the module in an orientation parallel to the module, rather than perpendicular to the module. Thus, the fiber does not need to bend to enter the module, which limits the thickness requirement of the module.

Advantageously, the side walls of the baseplate partition support hooks that mate with loops that extend from the top membrane of the cover. These hooks and loops ensure that the cover is firmly seated on the baseplate, which secures the module when it is handled and lasts for the duration of the use of the water-permeable connector.

Still in this preferred embodiment, the cover preferentially has a rib around the insert and extending perpendicularly from the top membrane; the partition of the baseplate is fitted into the gap between the rib and the cover insert so as to form a baffle across the mating interface between the cover and the baseplate. This baffle adds further obstacles to the penetration of water or dust into the watertight volume formed inside the baseplate.

According to a second aspect, the disclosed embodiments relate to a digital display panel comprising a set of modules according to the first aspect, juxtaposed in rows and/or columns. This panel allows for large display areas, for example for advertising displays.

### BRIEF DESCRIPTION OF THE FIGURES

The disclosed embodiments and the advantages resulting therefrom shall be apparent from the following embodiment, given as a non-limiting example, in support of the annexed figures wherein FIGS. 1 to 5 represent:

FIG. 1: A schematic representation in perspective view of the back of a module according to one embodiment;

FIG. 2: An exploded schematic representation of the module of FIG. 1;

FIG. 3: A first perspective view in cross-section of the module of FIG. 1;

FIG. 4: A second perspective view in cross-section of the module of FIG. 1;

FIG. 5: A third perspective view in cross-section of the module of FIG. 1; and

FIG. 6: A partial perspective view of the module of FIG. 1.

### DETAILED DESCRIPTION

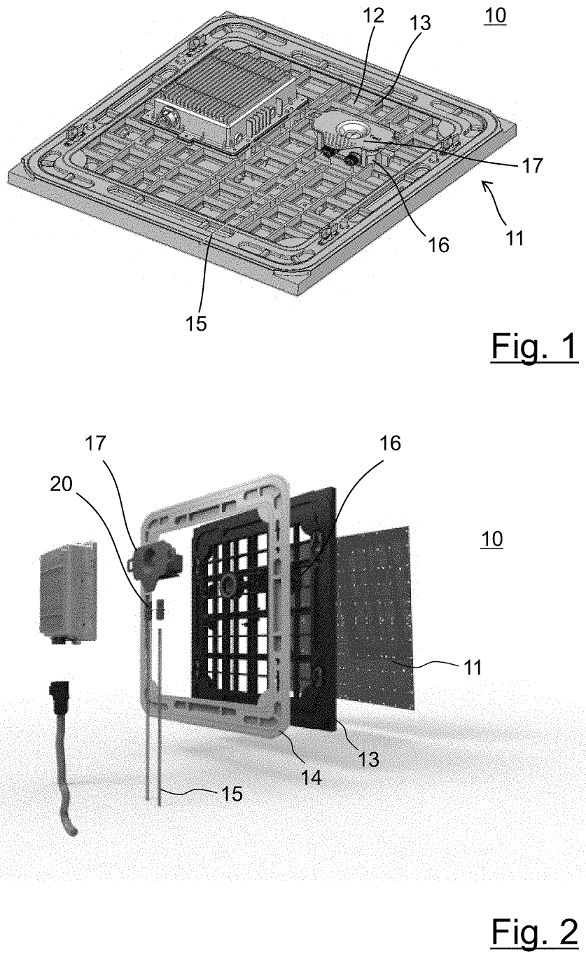

FIGS. 1 and 2 illustrate an LED module, i.e. a module 10 comprising an electronic board 11, a first face of which has an array of light-emitting diodes (or LEDs) arranged in rows and columns with a substantially constant pitch. The pitch between two LEDs may vary depending on the application, for example the pitch may be 4, 6 or 8 mm. The set of LEDs is soldered onto a first face of the electronic board 11. This electronic board 11 has holes opening onto a second face 12 of the electronic board 11 so as to allow the attachment of a frame 13.

This frame 13 comprises a central grid guaranteeing the mechanical strength of the electronic board 11 while allowing the thermal dissipation of the energy released by the light-emitting diodes. The use of a thermal resin can ensure thermal conductivity between the LEDs and the frame 13. This thermal resin can be obtained by assembling two compounds, for example an epoxy resin and a curing agent. On the edges of the frame 13, a fastening plate 14 is mounted. This mounting plate 14 is for mounting the module 10 to form a digital display panel. Indeed, a digital display panel typically comprises multiple modules 10 juxtaposed in rows and/or columns to form a large display surface.

Typically, a module 10 may have dimensions of about 40 by 43 cm, and the display area of a digital display panel may vary depending on the application, for example 6 m by 3 m, 4 m by 2 m, etc.

The disclosed embodiments relate to a watertight LED module 10. As used herein, a “watertight” module is one that is capable of withstanding a low-pressure water spray on all its faces. To ensure the sealing of the light-emitting diodes, the front face of the electronic board 11, i.e. the face intended to form the display surface, may be coated with a transparent resin. Similarly, the rear face 12 of the electronic board 11 may be coated with a thermal resin configured to allow heat dissipation of the electronic circuit and LEDs mounted on the electronic board 11.

In order to make the optical fiber connection watertight, a baseplate 16 is provided on the frame 13, and this baseplate 16 comprises at least one water-permeable optical fiber connector. In the example of FIGS. 1 to 5, the baseplate incorporates two water-permeable connectors 18, each connector 18 being capable of receiving a pair of optical fibers 15 so that the module 10 can receive a redundant signal, i.e. a signal transmitted by two separate optical fibers 15. The use of two connectors 18 allows data to be received and retransmitted to another module 10 so that all modules 10 in a panel can be cascade-connected.

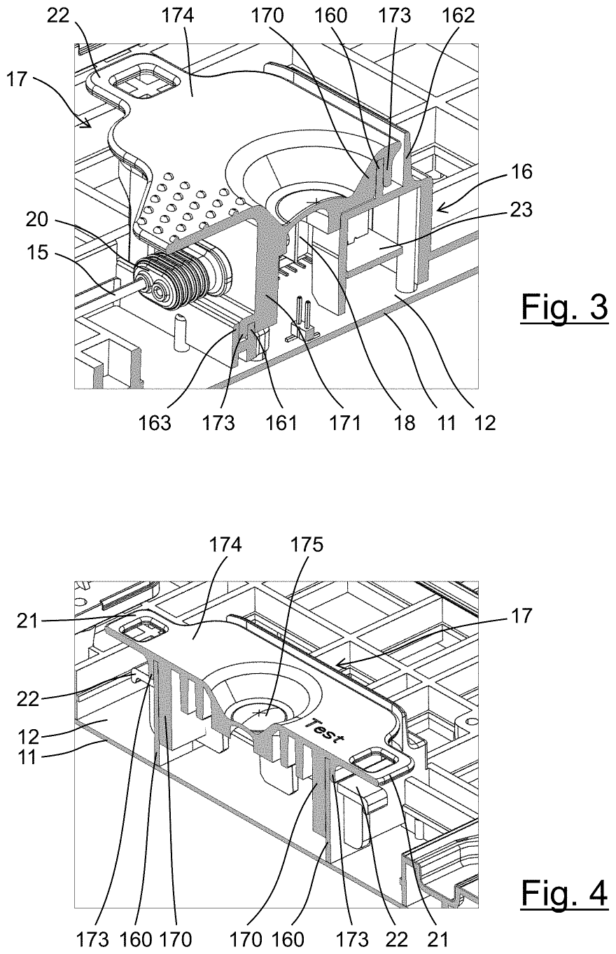

The water-permeable connectors 18 are mounted on a secondary electronic board, referred to as a connection board 23, shown in FIG. 3. This connection board 23 is itself electrically connected to the electronic board 11.

The water-permeable connectors 18 have a first open position 18a and a second closed position 18b shown in FIG. 6. The open position 18a allows the optical fiber(s) 15 to be inserted, while in the second closed position 18b, the optical fiber(s) 15 is/are held in place and cannot move or be removed from the connector 18.

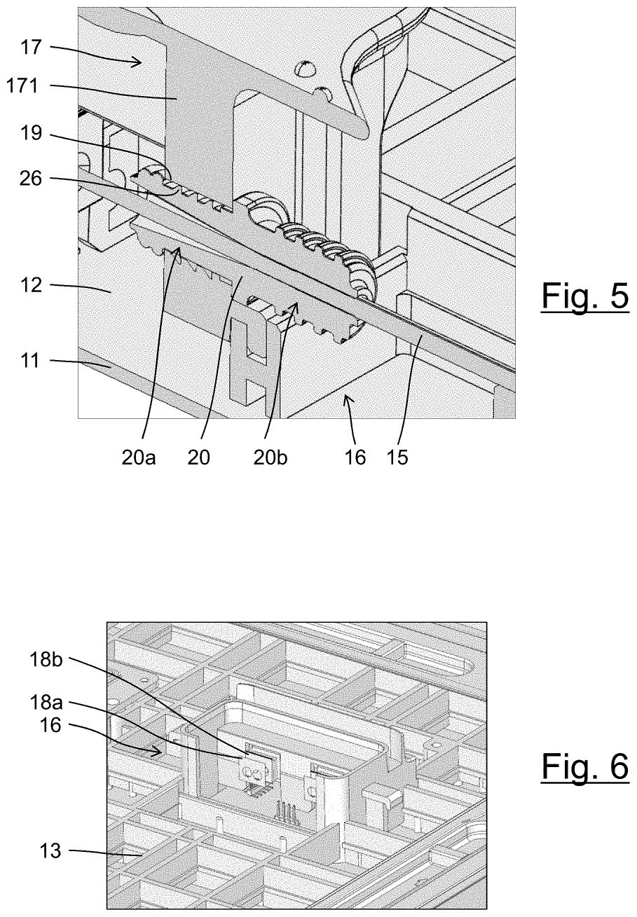

A cover 17 closes this baseplate 16 in a watertight manner, so that the water-permeable connectors 18 are protected. The optical fiber(s) 15 enter the watertight volume by passing through the cover 17 at openings 19 shown in FIG. 5. The sealing of these openings 19 is guaranteed by sealing means 20, which preferably correspond to plugs, as illustrated in FIG. 2.

FIGS. 3 and 4 illustrate the assembled module 10 in cross-section, and in particular show the partition 160 of the baseplate 16 extending vertically from the frame 13. This partition 160 defines a space in which the one or more water-permeable optical fiber connectors 18 are housed. Advantageously, the connectors 18 are arranged opposite a front wall of the partition 160, so that the optical fibers 15 do not have to bend to enter the baseplate 16. This saves space and results in a slimmer module 10. In addition, the optical fiber 15 can thus be attached to the frame 13 and therefore be secured. In order to leave a passage for the optical fibers 15, the partition 160 has a depression 161 on its front wall.

The cover 17 closes the baseplate 16 in a watertight manner by means of an insert 170 which penetrates the baseplate 16 and comes into contact with the partition 160 around its entire perimeter. At the depression 161, the insert 170 has a complementary protrusion 171. Thus, no space is left free, which prevents water from passing through.

Preferably, the external dimensions of the insert 170 are slightly larger than the internal dimensions of the partition 160 so that the clamping achieved during assembly ensures good contact between the surfaces of the insert 170 and partition 160. This mating ensures a good seal of the assembly as well as good retention of the cover 17 in the baseplate 16.

In addition, a rib 173 can be added to the cover 17 opposite the insert 170, so that the rib 173 and the insert 170 define a gap into which the partition 160 is fitted. In this way, the assembly creates a baffle, i.e. an alternation of deflectors of the cover 17 and baseplate 16 which oppose any penetration of water into the watertight volume.

Again, the thickness of the partition 160 is preferentially greater than the thickness of the gap defined by the insert 170 and the rib 173. This mating also ensures a good seal of the assembly as well as good retention of the cover 17 in the baseplate 16.

Advantageously, it is possible to make double walls 162, 163 on the baseplate 16 which supplement the baffle obtained. In addition, the module is generally arranged vertically with its connections coming from the bottom, as shown in FIG. 2. The double wall 162 is thus above the baseplate 16 and its height is sufficient to constitute a canopy which then protects the cover 17 from the rain.

Loops 21 extend on either side of the cover 17 in the extension of its top membrane 174, and are capable of hooking onto hooks 22 arranged on the side walls of the partition 160. For this purpose, the cover 17 can be made of elastomeric material, which allows it to be flexible.

FIG. 5 illustrates in detail the passage of an optical fiber 15 through an opening 19 in the cover 17, and the means 20 for sealing this passage. In the preferred embodiment illustrated, the means 20 is a plug, the orifice of which advantageously comprises two portions 20a, 20b. The first portion 20a is frustoconical, with a first section having a diameter greater than the diameter of the fiber 15 and opening inside the baseplate 16, and a second section, on the opposite face, having a diameter less than the diameter of the optical fiber 15.

This arrangement allows the optical fiber 15 to be inserted into the orifice of the plug 20 without difficulty in the portion 20a of the orifice of the plug 20 from the first section, the portion 20a being frustoconical and acting as a funnel.

Furthermore, the second section of the portion 20a slightly clamps the optical fiber 15, thereby providing a seal by preventing water from entering between the optical fiber 15 and the wall of the orifice of the plug 20, and retaining the optical fiber 15 by preventing it from slipping

Advantageously, the second section of the portion 20a opens onto a cylindrical portion 20b of the orifice of the plug 20, this second portion 20b is cylindrical and also has a diameter less than the diameter of the optical fiber 15. Thus, the clamping length that guarantees the sealing and the retention of the optical fiber 15 is increased and the performance is thus improved.

In this preferred embodiment, the plug 20 has protrusions 26 provided on its outer face. The external dimensions of the protrusions 26 are greater than the internal dimensions of the opening 19 so that the protrusions 26 deform and are squeezed into the opening 19.

Advantageously, these protrusions 26 are triangular in shape and the chamfer is on the inner face of the baseplate 16, so that insertion of the plug 20 into the orifice 19 is facilitated and its removal is hindered, the orientation of this triangular shape also constituting an obstacle to the penetration of water on the inner face of the baseplate 16.

For this purpose, the front wall 171 of the insert 170 of the cover 17 is thickened, so that the length of the interface between the opening 19 and the plug 20 is sufficient, and the number of protrusions 26, if any, is sufficient. The increased thickness of the front wall 171 is then at least twice the nominal thicknesses of the other parts of the cover 17.

This thickening of the front wall 171 of the insert 170 of the cover 17 also gives it more rigidity, which is beneficial when inserting the plug 20 into the orifice 19. Advantageously, the side walls of the insert 170 of the cover 17 are also thickened, thereby contributing to the strength of the insert 170 and reducing deformation of the assembly during insertion or removal of the plugs 20.

In a particular embodiment, the module 10 includes a button for testing the connectivity provided between the optical fibers 15 and the water-permeable optical fiber connectors 18. In order for this button to be protected, in cases where this button is water-permeable, it is placed within the watertight volume consisting of the baseplate 16 and the cover 17. In order for this button to be activated without removing the cover 17, it is conceivable to make a shape 175 on the cover 17, and advantageously on its top membrane 174, giving that point on the cover 17 the necessary flexibility so that the user can press the shape 175, so that it sinks in, and pushes against the test button located underneath.

The disclosed embodiments thus make it possible to obtain a module 10 receiving its control data via optical fibers 15 by means of high-performance connectors and implemented in a sealed environment 18.

1. A module for a digital display panel, the module comprising:
an electronic board, a first face of which has an array of light-emitting diodes arranged in rows and columns with a substantially constant pitch;
a frame fastened onto a second face of the electronic board opposite the first face; and
at least one water-permeable connector, for an optical fiber, mounted on the frame;
wherein the frame comprises a baseplate integrating the at least one water-permeable connector; and wherein the module further comprises a cover attached to the baseplate so as to form a watertight volume inside the baseplate, the cover comprising at least one opening provided with sealing means intended to ensure sealing around at least one optical fiber connected to the at least one water-permeable connector.

2. A module according to claim 1, wherein the sealing means correspond to a plug inserted in the opening of the cover.

3. A module according to claim 2, wherein the plug has at least one orifice intended to allow the passage of an optical fiber having a predetermined diameter; the orifice comprising a frustoconical portion having a first cross-section whose diameter is greater than the predetermined diameter and a second cross-section whose diameter is less than the predetermined diameter; the first cross-section of the frustoconical portion opening out into the volume of the baseplate.

4. A module according to claim 3, wherein the orifice further comprises a cylindrical portion opening, at a first end, onto the second section of the frustoconical portion; a second end of the cylindrical portion, opposite the first end, opening outside the volume of the baseplate.

5. A module according to claim 1, wherein the plug comprises protrusions extending radially from an outer face, the protrusions having an outer diameter greater than the internal dimensions of the opening of the cover so as to hold the plug in the opening of the cover by deformation of the protrusions.

6. A module according to claim 1, wherein the baseplate comprises a partition rising from the frame, and wherein the cover has a top membrane and an insert extending perpendicular to the top membrane; the seal between the baseplate and the cover being provided by mating between the partition of the baseplate and the insert of the cover.

7. A module according to claim 6, wherein the partition of the baseplate and the insert of the cover comprise a front wall, a rear wall and side walls; the front wall of the partition of the baseplate comprises a depression facing the at least one water-permeable connector; the front wall of the cover has a protrusion whose shape corresponds to that of the depression of the front wall of the baseplate, and the at least one opening of the cover is formed in the front wall of the cover so that the at least one optical fiber can come to face the water-permeable connector.

8. A module according to claim 7, wherein the side walls of the partition of the baseplate support hooks which mate with loops that extend from the top membrane of the cover.

9. A module according to claim 6, wherein the cover has a rib disposed around the insert and extending perpendicularly from the top membrane; the partition of the baseplate is fitted into the gap between the rib and the insert of the cover so as to form a baffle across the mating interface between the cover and the baseplate.

10. A digital display panel comprising a set of modules, according to claim 1, juxtaposed in rows and/or columns.
